(19) United States
(12) Patent Application Publication
(10) Pub. No.: US 2009/0273406 A1
(43) Pub. Date: Nov. 5, 2009

(54) MECHANICALLY TUNABLE PRINTED RESONATOR

(76) Inventors: Roger John Hubert, Hudson, NH (US); Tom Dexter Woodward, Brentwood, NH (US)

Correspondence Address: JAECKLE, FLEISCHMANN & MUGEL, LLP, 8th Floor, 12 Fountain Plaza, Buffalo, NY, 14202-2922, US

(21) Appl. No.: 12/113,873

(22) Filed: May 1, 2008

(51) Int. Cl. H03B 5/30

(52) U.S. Cl. 331/154

(57) ABSTRACT

A mechanically tunable printed resonator is provided. The mechanically tunable printed resonator includes a tuning element support maintaining a tuning element a distance above the printed resonator.

### BACKGROUND OF THE INVENTION

This invention relates generally to printed resonators or printed resonance circuits, and more particularly, to a mechanically tunable printed resonator.

Printed resonance circuits, and in particular, high frequency printed resonance circuits are often used in radio devices, for example, transmitters, receivers, etc. In general, these printed resonance circuits are often used in radio frequency (RF) and microwave electronics applications to provide a frequency reference in an oscillator circuit. For example, microwave transceivers may be used in radar systems, communication systems, intrusion detection systems, etc. One way a microwave transceiver generates microwave radiation is using a transistor oscillator. For example, a transistor oscillator using a field effect transistor (FET) or a bipolar transistor may generate a signal within a desired frequency range, which may be used in connection with a high-Q dielectric resonator to stabilize the operation of the oscillator. The resonator is coupled to, for example, the transmitting device, such that the device is only capable of oscillating at a specific frequency determined by the resonator. Accordingly, a signal is generated at the frequency based on the oscillation conditions.

Known systems set the frequency of an oscillator by precisely locating a high-Q ceramic disc at a specific location in a circuit to act as a resonant filter. The resonance frequency of the disc can then be adjusted by moving a metal plate that is suspended over and parallel to the surface of the disc. This type of oscillator is commonly known as a Dielectric Resonator Oscillator (DRO). This DRO technology, however, can be problematic to operate (e.g., tune) and expensive to manufacture. These problems are due in part to the material variability of the disc and the precision required to locate the disc in each oscillator to facilitate the fine tuning of the final set frequency for the oscillator. Moreover, it is often difficult and time consuming to adjust the frequency of these oscillators.

Moreover, setting the final center frequency of an oscillator for a printed resonance circuit that may form part of, for example, a transmit/receive module, typically requires physically cutting or trimming the resonator/filter or transmission line elements contained in the feedback circuit. This process adds time and cost to the manufacture of the modules, and becomes increasingly problematic as the frequency of desired oscillation increases and/or the resonant structures become incrementally smaller. Moreover, oscillation frequency variability can become a problem with high volume Surface Mount Technology (SMT) wherein placements of active and passive components on a circuit board that forms the source/load impedance for the resonant structure, which is a critical part of the oscillator, can vary greatly.

### BRIEF DESCRIPTION OF THE INVENTION

In accordance with an exemplary embodiment, a tunable oscillator is provided that includes a printed resonator. The tunable oscillator also includes a tuning element support maintaining a tuning element a distance above the printed resonator.

In accordance with another exemplary embodiment, a tuning element for an oscillator is provided. The tuning element includes an engagement portion configured to engage a cover for the oscillator and a ceramic rod attached to the engagement portion. The engagement portion is configured to maintain the ceramic rod a distance above a printed resonator of the oscillator.

In accordance with yet another exemplary embodiment, a method of mechanically tuning a printed resonator is provided. The method includes maintaining a ceramic rod above the printed resonator and adjusting a distance between the ceramic rod and the printed resonator. The adjustment is performed mechanically.

### BRIEF DESCRIPTION OF THE DRAWINGS

FIG. 1 is a block diagram of an oscillator in connection with which various embodiments of the invention may be implemented.

FIG. 2 is a bottom plan view of a cover having an opening for receiving a tuning element in accordance with various embodiments of the invention.

FIG. 3 is a side elevation view of the cover of FIG. 2 showing a passage therein.

FIG. 4 is a top plan view of the cover of FIG. 2.

FIG. 5 is a top plan view of a cover having a tuning element therein constructed in accordance with various embodiments of the invention.

FIG. 6 is a side cross-sectional view of the cover of FIG. 5 taken along the line 6-6 of FIG. 5.

FIG. 7 is top plan view of a transceiver module illustrating the positioning of a tuning element in accordance with various embodiments of the invention.

FIG. 8 is a top plan view of a transceiver module illustrating the positioning of a tuning element in accordance with another embodiment of the invention.

### DETAILED DESCRIPTION OF THE INVENTION

For simplicity and ease of explanation, the invention will be described herein in connection with various embodiments thereof. Those skilled in the art will recognize, however, that the features and advantages of the various embodiments may be implemented in a variety of configurations. It is to be understood, therefore, that the embodiments described herein are presented by way of illustration, not of limitation.

As used herein, an element or step recited in the singular and proceeded with the word “a” or “an” should be understood as not excluding plural said elements or steps, unless such exclusion is explicitly stated. Furthermore, references to “one embodiment” of the present invention are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property. Additionally, the arrangement and configuration of the various components described herein may be modified or change, for example, replacing certain components with other components or changing the order or relative positions of the components.

Various embodiments of the invention provide a finitely adjustable dielectric element that allows for tuning of a printed resonant circuit or other resonant structure. The printed resonant circuit may form part of an oscillator or transmit/receive module. In operation, the adjustable element changes the oscillation frequency by perturbing the electric field present at the surface of a printed microstrip transmission line or resonant structure (and transmission line associated with the feedback loop of the oscillator).

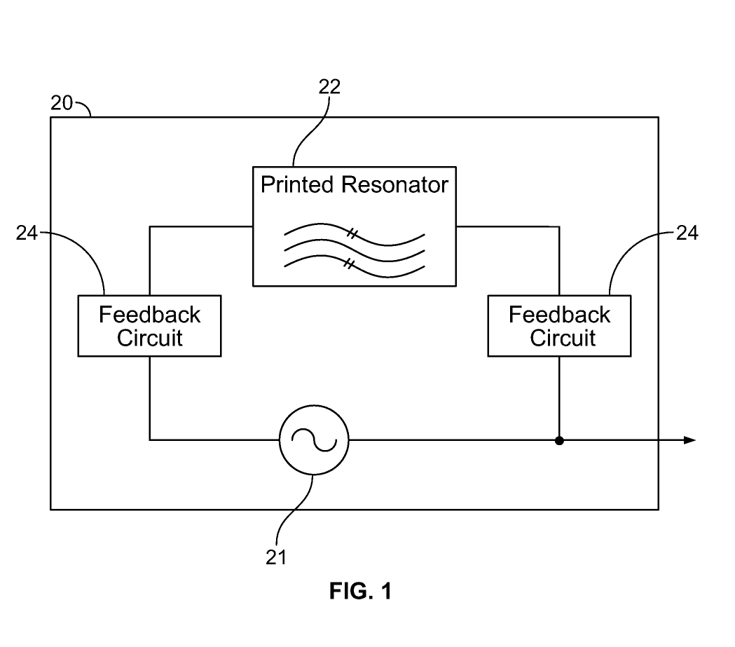

The various embodiments may be implemented as part of an oscillator 20 as shown in FIG. 1. The oscillator 20 may form part of a communication module such as a transmit/receive (transceiver) module or the oscillator 20 alone may form part of the transmit/receive module. The oscillator 20 generally includes an oscillator source 21 (e.g., a heterojunction bipolar transistor (HBT) or a junction gate field-effect transistor (JFET)) and a printed resonator 22, for example, a transmission line resonator network formed on a printed circuit board. However, the oscillator source 21 optionally may be a separate standalone and/or separate unit from the oscillator 20. A feedback circuit 24 (represented as two components) is also provided, which may be separate from or included as part of the printed resonator 22. Thus, over a desired or required frequency range the printed resonator 22 may be tuned as described below to define a final center frequency of the oscillator 20 based on the tuning of the printed resonator 22. It should be noted that the printed resonator 22 may be formed in different configurations using any type of printed resonance circuit.

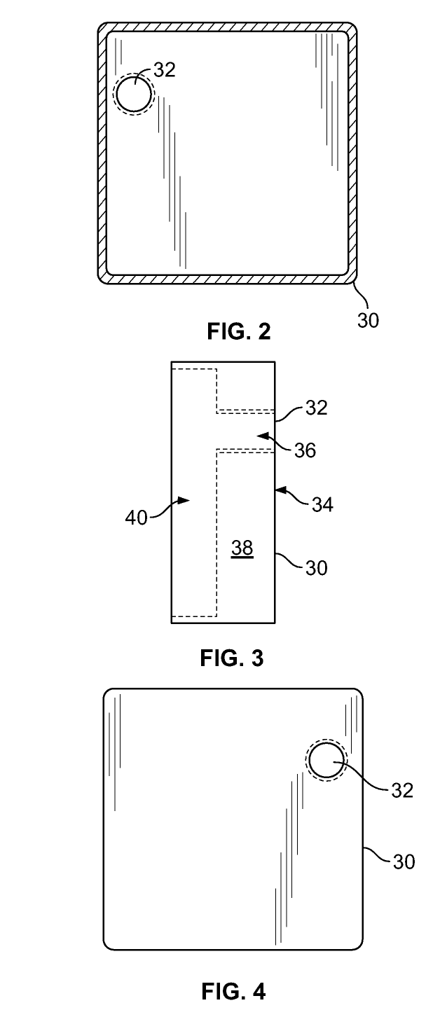

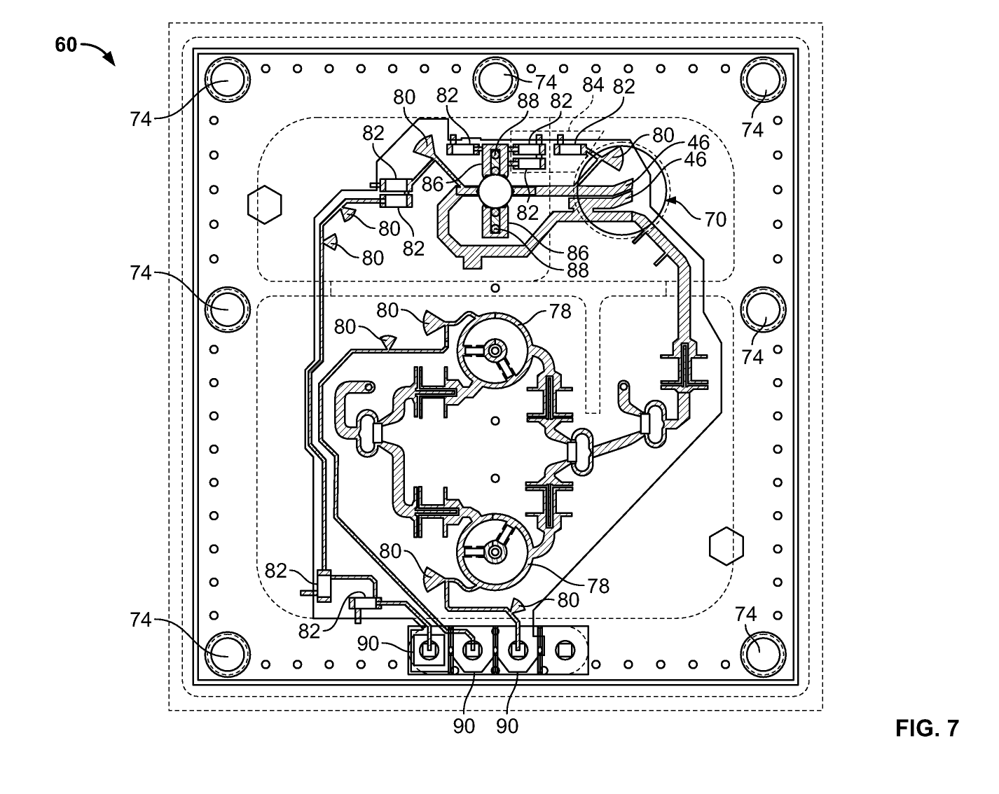

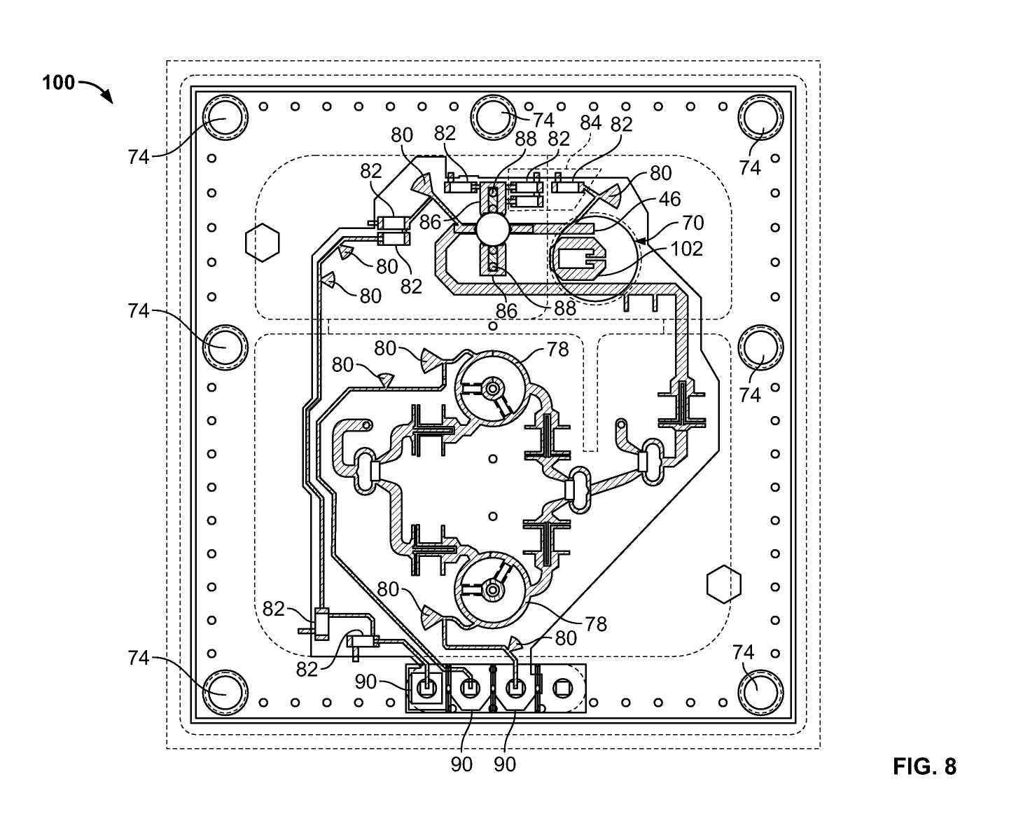

In one embodiment, a tuning mechanism for the printed resonator 22, which may be mechanically adjusted by a user, is provided in combination with a tuning element support, which in one embodiment is a cover 30 (or housing) for a printed resonator 22 as shown in FIGS. 2 through 4. However, the tuning element support may be any structure or component configured to support the tuning mechanism. The cover 30 may be configured for connection to an oscillator circuit or transceiver module 60 as shown in FIG. 7 or the transceiver module 100 shown in FIG. 8. The cover 30 may be formed from any suitable material, for example, a metal or metal composite. The cover 30 is generally sized and shaped based on the requirements of the component, such as the transceiver module 60 or 100, to which the cover 30 is to be connected. The cover 30 includes an opening 32 in a top surface 34 of the cover 30. A passage 36 extends from the opening 32 in the top surface 34 into the body 38 of the cover 30. The passage 36 extends through the body 38 to a cavity 40 defined within the cover 30. The cavity 40 allows connection to components therein and covers or encompasses some or all of the components including, for example, the printed resonator 22 to provide oscillation operation.

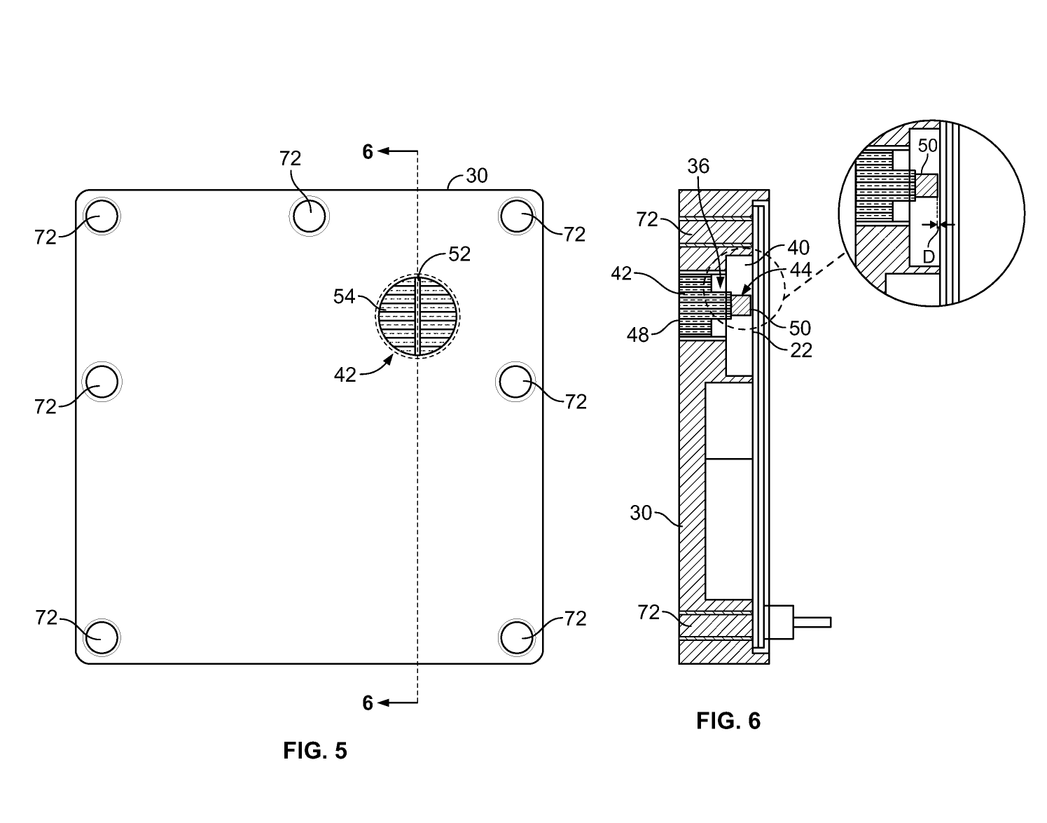

The passage 36 extends generally vertically from the top surface 34 to the cavity 40. The passage 36 is configured to receive therein a tuning element 42 as shown in FIG. 5 and 6 that includes a rod 44 and an engagement portion 48. Accordingly, the passage 36 is sized and shaped to accommodate receiving and securing therein the tuning element 42 such that the tuning element 42 is positioned above the printed resonator 22. The passage 36 in one embodiment is generally cylindrical and may include grooved or threaded walls to engage complimentary grooves or threads on the tuning element 42. However, it should be noted that the walls of the passage 36 may be smooth or may be smooth along a portion and grooved or threaded along another portion. Also, the tuning element 42 may be formed or threaded in such a manner as to lock or secure itself within the passage 36 as the tuning element 42 is screwed therein.

In one embodiment, as shown in FIGS. 5 through 7, the cover 30 is configured to connect to a transceiver module 60 such that a rod 44 is positioned above and generally perpendicular to the printed resonator 22, which in this embodiment is a printed resonator circuit of the oscillator 20 that forms the oscillation control portion of the transceiver module 60. Accordingly, the passage 36 is formed and positioned in the cover 30 such that when the tuning element 42 is received therein (e.g., inserted therein), the rod 44 extends into the cavity 40 and is held above the printed resonator 22 and transmission lines 46 (shown in FIG. 7) that form part of the feedback circuit of the transceiver module 60. In operation, the positioning of the rod 44 above the printed resonator 22 and transmission lines 46 affects both the wavelength and insertion phase in this section of the circuit of the transceiver module 60, such that the resonant frequency may be changed.

It should be noted that the cover 30 may include one or more cavities 40 having different components, for example, of the transceiver module 60 therein. Each of the cavities 40 may have an opening 32 and corresponding passage 36 providing access thereto, or only some or one of the cavities 40 may have an opening 32 and passage 36.

Referring more particularly to the tuning element 42 having the rod 44 in accordance with various embodiments of the invention, the rod 44 extends from an engagement portion 48 of the tuning element 42. Accordingly, a top portion of the tuning element 42 is formed by the engagement portion 48 and a bottom portion of the tuning element 42 is formed by the rod 44. The engagement portion 48 and rod 44 are fixedly connected to one another in any suitable manner that provides a permanent or secure connection. For example, in one embodiment the engagement portion 48 and rod 44 are glued together (e.g., bonded together with epoxy) to form the tuning element 42. As another example, the rod 44 may be press fit into the engagement portion 48.

The engagement portion 48 is configured to be secured within the passage 36 such that the rod 44 extends into the cavity 40. The engagement portion 48 is configured to allow user adjustment of the engagement portion 48 to determine the depth to which the engagement portion 48 extends into the passage 36. Accordingly, a distance D between an end 50 of the rod 44 and the printed resonator 22 may be adjusted by a user. Thus, a gap between the rod 44 and the printed resonator 22 is user adjustable.

In various embodiments, adjustment of the tuning element 42 is provided by turning or screwing the tuning element 42 into the passage 36 (e.g., the engagement portion 48 includes a screw socket). For example, in one embodiment, a notch 52 is provided on a top surface 54 of the engagement portion 48 of the tuning element 42 to facilitate turning or screwing the tuning element 42. The notch 52 may be, for example, a slot to receive a flat head screwdriver or similar device therein (or other type of manual or automated tooling device). The notch 52 alternatively may be shaped to receive therein a Philips-head screwdriver or similar device. However, it should be noted that the notch 52 may be shaped and sized differently to accommodate different types of tools. For example, the notch 52 may be configured to engage only a specialized tool such that, for example, only authorized or trained individuals can turn the tuning element 42.

The engagement portion 48 may be, for example, a threaded metal holder configured to engage the passage 36 when screwed therein and secure the rod 44 above the printed resonator 22 at the distance D to thereby adjust the frequency of the oscillator 20 by affecting the wavelength and phase of the printed resonator 22. For example, the rod 44 may be formed of a ceramic material (e.g., alumina) having a known dielectric value and diameter. Accordingly, as the tuning element 42 is screwed further into the passage 36, the distance D between the rod 44 and the printed resonator 22 decreases, thereby changing the free running oscillation of the oscillator 20 (by changing the wavelength and phase of the printed resonator 22), namely decreasing the oscillation frequency. It should be noted the rod 44 may be formed of any suitable material capable of affecting the wavelength and phase of the printed resonator 22 to achieve a desired or required oscillation frequency. For example, the rod 44 may be cylindrically shaped and formed of a material that is proportional to frequency at a particular dielectric quantification. In general, the ceramic material may be formed as any shape or size of ceramic member.

The engagement portion 48 may be formed in different configurations to allow the engagement portion 48 to be adjusted by a user and thereafter remain in that position within the passage. In one embodiment, the engagement portion 48 is configured as a threaded metal holder having a fine pitch thread of about sixty-four threads per inch. In another embodiment, the threads may be serrated threads. In yet another embodiment, the threads engage complementary threads within the passage 36. In general, the thread pitch is selected or configured, for example, to allow a required or desired amount of incremental tuning (e.g., reasonably fine tuning) of the oscillation frequency. However, it should be noted that the engagement portion 48 may be secured within the passage 36 using means other than threads. For example, a glue compound or other similar compound that allows adjustment of the tuning device 42 and then bonds to the passage 36 may be provided. It should be noted that even when threads are used, an epoxy or similar material may be applied to, for example, the top 54 of the engagement portion 48 to secure the tuning element 42 within the passage 36 and also to prevent future adjustment (e.g., screwing) of the tuning element 42. However, the notch 52 may be left exposed to allow adjustments at different times, for example, in the factory, in the field, during maintenance, at scheduled intervals, etc. For example, when the tuning elements 42 are used in different oscillators 20, such as in a plurality of devices in close proximity (e.g., door openers in a store), the frequencies of the oscillators 20 may be staggered to avoid cross talk or interference between the plurality of devices. Accordingly, a technician in the field installing the devices may adjust the frequency of each oscillator when installing the devices, with each oscillator 20 set to a different staggered frequency using the tuning element 42 of the various embodiments.

The size and shape of the tuning element 42 may be varied. For example, the diameter of the engagement portion 48 and/or the rod 44 of the tuning element 42 may be varied to obtain different tuning characteristics. For example, and with reference to the transceiver module 60 as shown in FIG. 7 or the transceiver module 100 shown in FIG. 8, the transceiver module 60 or 100 may be about 1.5 inches square with the engagement portion 48 having a diameter of about 2/10 of an inch, or about the size of a #10 screw. In this embodiment, the rod 44 is about sixty-two one-hundredths of an inch in diameter (with the transmission lines 46 shown in FIG. 7 about 22 one-hundredths of an inch wide). However, the size and shapes of the engagement portion 48 and rod 44 may be changed as desired or required, for example, based on the particular application, device, etc.

Accordingly, the engagement portion 48 of the tuning element 42 secures and maintains the rod 44 at a user selectable distance from the printed resonator 22. In one embodiment, the rod 44 is maintained in this selected position above the printed resonator 22. The circle area 70 represents the location of the tuning element 42 above the transmission lines 46 of the transceiver module 60. In this embodiment, the transmission lines 46 act as the printed resonator 22. The coupling values and phase between the transmission lines 46 is affected by the distance between the rod 44 and the transmission lines 46, when the rod 44 is maintained above the transmission lines 44. Accordingly, in this embodiment, the opening 32 in the cover 30 (both shown in FIGS. 2 through 4) is positioned such that when the cover 30 is connected to the transceiver module 60, the rod 44 is positioned above the transmission lines 46 such that the distance between the rod 44 and the transmission lines 46 adjusts the oscillation frequency of the transmission lines 46 (acting as the printed resonator 22). It should be noted, that the positioning of the opening 32 in the cover 30 may be changed (and additional openings 32 provide for receiving therein additional tuning elements 42) based on the location of the printed resonator 22 when the cover is attached to the device having the printed resonator 22 therein. In general, the opening 32 is positioned in the cover 30 such that the rod 44 is positioned over and perpendicular to the printed resonator 22.

It also should be noted that additional openings 72 may be provided in cover 30 (shown in FIGS. 5 and 6) to receive therein fasteners (e.g., screws) to mount the cover 30 to a device, which in one embodiment is the transceiver module 60 (shown in FIGS. 7 and 8). The fasteners extend through the openings 72 into opening 74 (shown in FIGS. 7 and 8) to provide the secure engagement. Additional openings (not shown) also may be provided in transceiver module 60, for example, at the corners of the transceiver module 60, to receive fasteners (e.g., screws) to mount the covered transceiver module 60 into, for example, a sensor, such as a sensor above an automatic opening door.

The transceiver module 60 includes components that are known to one skilled in the art and connected to provide transmit and receive operation in any know manner. For example, mixers 78 may be provided to mix the various transmitted and received signals as is known. Additionally, chokes 80 and resistors 82 may be provided as are known. The resistors 82, for example, may be connected to form a bias network 84 as is also known. A transistor (not shown) may be mounted to pads 86 that are connected to vias 88 (e.g., metal vias for transistor connections). Accordingly, the bias network 84 may be provided between a field-effect transistor (FET) or other transistor mounted on the pads 86 and ground to self bias the FET. Terminals 90 (e.g., input and output terminals) also may be provided as are known to provide connection to the transceiver module 60.

The various embodiments may be implemented in connection with different transceiver modules. For example, a transceiver module 100 similar to the transceiver module 60 may be provided wherein like numerals represent like parts. However, the transceiver module 100 includes a printed resonator configured as a horseshoe resonator 102. The circle area 70 represents the location of the tuning element 42 above the horseshoe resonator 102 of the transceiver module 100. Thus, it should be appreciated that the adjustable tuning element of the various embodiments may be provided in combination with different types of printed resonators.

Thus, various embodiments provide an adjustable tuning element that allows a user settable oscillation frequency. For example, a printed resonator and transmission lines of an oscillator may be formed to filter frequencies in an approximate particular frequency, such as 24 GHz plus or minus a variance (e.g., plus or minus 100 MHz). This frequency range is determined, for example, based on the length and width of the transmission lines and/or the configuration of the printed resonator. Various embodiments allow precise setting of the final center frequency by mechanically adjusting the tuning element to change the distance between the ceramic rod of the tuning element and the printed resonator and/or transmission lines. Accordingly, more precise setting of the final oscillation frequency by a user is provided without having to physically cut, trim or otherwise externally load the resonator/transmission lines. Also, a high volume manufacturing method and low cost mechanical solution for precise setting of the final center frequency of an oscillator, such as in a transceiver module, may be provided.

It should be noted that modifications and variations to the various embodiments are contemplated. For example, the number, relative positioning and operating parameters of the various components may be modified based on the particular application, use, etc. The modification may be based on, for example, different desired or required operating characteristics.

Accordingly, it is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope. Dimensions, types of materials, orientations of the various components, and the number and positions of the various components described herein are intended to define parameters of certain embodiments, and are by no means limiting and are merely exemplary embodiments. Many other embodiments and modifications within the spirit and scope of the claims will be apparent to those of skill in the art upon reviewing the above description.

The scope of the various embodiments of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means-plus-function format and are not intended to be interpreted based on 35 U.S.C. §112, sixth paragraph, unless and until such claim limitations expressly use the phrase “means for” followed by a statement of function void of further structure.

What is claimed is:

1. A tunable oscillator comprising:
a printed resonator; and
a tuning element support maintaining a tuning element a distance above the printed resonator.

2. A tunable oscillator in accordance with claim 1 wherein the tuning element comprises a ceramic rod.

3. A tunable oscillator in accordance with claim 1 wherein the tuning element comprises an engagement portion having a threaded metal holder.

4. A tunable oscillator in accordance with claim 3 wherein the threaded metal holder comprises about sixty-four threads per inch.

5. A tunable oscillator in accordance with claim 1 further comprising a cover having an opening configured to receive therein the tuning element.

6. A tunable oscillator in accordance with claim 1 wherein the tuning element comprises an engagement portion having a notch on a top surface.

7. A tunable oscillator in accordance with claim 1 further comprising a cover configured to maintain the tuning element substantially perpendicular to the printed resonator.

8. A tunable oscillator in accordance with claim 1 wherein the printed resonator comprises a plurality of transmission lines.

9. A tunable oscillator in accordance with claim 1 wherein the tuning element is mechanically adjustable.

10. A tunable oscillator in accordance with claim 9 wherein the mechanical adjustment comprises one of screwing and turning the tuning element.

11. A tunable oscillator in accordance with claim 1 wherein the tuning element comprises an alumina rod.

12. A tunable oscillator in accordance with claim 1 wherein the tuning element support comprises a cover and further comprising an engagement portion that secures the tuning element in the cover.

13. A tuning element for an oscillator comprising:
an engagement portion configured to engage a cover for the oscillator; and
a ceramic rod attached to the engagement portion, the engagement portion configured to maintain the ceramic rod a distance above a printed resonator of the oscillator.

14. A tuning element in accordance with claim 13 wherein the ceramic rod is bonded to the engagement portion.

15. A tuning element in accordance with claim 13 wherein the ceramic rod is press fit into the engagement portion.

16. A tuning element in accordance with claim 13 wherein the ceramic rod comprises alumina.

17. A tuning element in accordance with claim 13 wherein the ceramic rod comprises a predetermined dielectric value and diameter.

18. A tuning element in accordance with claim 13 wherein the engagement portion comprises a threaded metal holder having threads configured to secure the engagement portion within a passage of the cover, the passage above the printed resonator.

19. A tuning element in accordance with claim 13 wherein the engagement portion includes one of a slot, notch and socket configured to engage one of a screwdriver, a manual tooling device and an automated tooling device.

20. A method of mechanically tuning a printed resonator:
maintaining a ceramic rod above the printed resonator; and
adjusting a distance between the ceramic rod and the printed resonator, the adjustment performed mechanically.
